(19) United States
(12) Patent Application Publication
(10) Pub. No.: US 2011/0033668 A1
(43) Pub. Date: Feb. 10, 2011

(54) APPARATUS AND METHOD FOR ILLUMINATING THROUGH A CIRCUIT BOARD

(76) Inventors: Richard A. Boelstler, Lake Orion, MI (US); Daniel W. Hodgman, Royal Oak, MI (US); Habib I. Baydoun, Dearborn Heights, MI (US); Eluid David Carter, Southfield, MI (US); Timothy S. Williams, Holly, MI (US)

Correspondence Address: BLANK ROME LLP, WATERGATE, 600 NEW HAMPSHIRE AVENUE, N.W., WASHINGTON, DC, 20037, US

(21) Appl. No.: 12/628,114

(22) Filed: Nov. 30, 2009

Related U.S. Application Data
(60) Provisional application No. 61/232,263, filed on Aug. 7, 2009.

(51) Int. Cl. B32B 3/00; B32B 37/12; H05K 1/18; F21V 21/00

(52) U.S. Cl. 428/161; 156/60; 156/275.5; 174/260; 362/382

(57) ABSTRACT

An assembly includes a substrate, a flexible layer, and an adhesive mating the substrate and the flexible layer. The substrate has a first surface and a second surface opposite the first surface. The flexible layer has a first surface and a second surface opposite the first surface. The flexible layer has a thickness such that light passes through the flexible layer without substantial change to a color or an intensity of the light and such that the flexible layer substantially conforms to a shape of the substrate. The adhesive mates the second surface of the substrate and the first surface of the flexible layer and has a viscosity that substantially fills in a texture of at least one of the second surface of the substrate and the first surface of the flexible layer. The adhesive also forms substantially no air gaps.

### REFERENCE TO RELATED APPLICATION

The present application claims the benefit of U.S. Provisional Patent Application No. 61/232,263, filed Aug. 7, 2009, whose disclosure is hereby incorporated by reference in its entirety into the present disclosure.

### FIELD OF THE INVENTION

The present invention relates to illuminating through a circuit board. In particular, the present invention relates to an assembly and a method for illuminating through a circuit board so that the light from the light source substantially maintains its color and intensity.

### BACKGROUND OF THE INVENTION

Known circuit boards are made from dielectric materials that are opaque. For example, many circuit boards are made from dielectric materials, such as Flame Retardant 4 or FR4, which is formed from woven glass and epoxy, or some other epoxy-based material. Such dielectric materials are usually green or yellow, and the green or yellow coloring is inconsistent. Thus, when these dielectric materials are backlit or illuminated such that light has to travel through the dielectric material, the light traveling through the dielectric material changes color or loses its intensity. That is, the dielectric material filters the light that travels through it. Therefore, the light source that provides the light that travels through the dielectric material must emit a light with a color that compensates for the filtering or emit a light with a stronger intensity. However, a light source that emits a light with stronger intensity consumes more power and produces more heat.

Thus, a dielectric material that compensates for the filtering of light is needed. However, known dielectric material that compensate for the filtering of light, such as polyester flex circuits, are not compatible with lead free solders or two-sided traces. Also, polyester flex circuits cannot withstand the heat required for lead free solders. Lead-free solder is needed for certain circuit elements or components, for example, those associated with capacitive or field effect circuits and sensors. Thus, known dielectric material cannot be used with such circuit elements or components.

Also, known dielectric materials do not adhere well to another surface. In some applications, printed circuit boards are mated to another surface for mounting or mechanical support. If the other surface has an irregular shape or a non-planar contour, the known printed circuit board does not have the flexibility to conform to the irregular shape or the non-planar contour. Furthermore, pressure sensitive tape and adhesives are used to mate the printed circuit board to another surface. However, pressure sensitive tape and adhesives are prone to forming air gaps between the printed circuit board and the other surface, thereby forming thick, unreliable, and non-uniform bonding between printed circuit boards and their mating surfaces. Also, for devices using capacitive or field effect circuits and sensors, air gaps impair their performance. Furthermore, pressure sensitive tape and adhesives change the color or intensity of light passing through them.

Thus, there is a need for a dielectric material that can be backlit such that the light traveling through the dielectric material does not substantially change color or lose its intensity. If the dielectric material is mated to another surface, the mating should be thin, reliable, uniform, and allow light to pass without substantially changing its color or intensity. Also, the same dielectric material should be compatible with lead free solder and two-sided traces. Furthermore, the dielectric material should be flexible so that it can conform to the contours of another surface.

### SUMMARY OF THE INVENTION

Accordingly, an aspect of the invention may provide an assembly that includes a substrate, a flexible layer, and an adhesive mating the substrate and the flexible layer. The substrate has a first surface and a second surface opposite the first surface. The flexible layer has a first surface and a second surface opposite the first surface. The flexible layer has a thickness such that light passes through the flexible layer without substantial change to a color or an intensity of the light and such that the flexible layer substantially conforms to a shape of the substrate. The adhesive mates the second surface of the substrate and the first surface of the flexible layer and has a viscosity that substantially fills in a texture of at least one of the second surface of the substrate and the first surface of the flexible layer. The adhesive also forms substantially no air gaps.

Another aspect of the invention may provide an assembly that includes a substrate, a flexible layer, and an adhesive mating the substrate and the flexible layer. The substrate has a first surface and a second surface opposite the first surface and allows some portion of light to pass through the first surface and the second surface. The flexible layer has a first surface and a second surface opposite the first surface and allows some portion of light to pass through the first surface and the second surface. The flexible layer has a thickness such that light passes through the flexible layer without substantial change to a color or an intensity of the light and such that the flexible layer substantially conforms to a shape of the substrate. The adhesive mates the second surface of the substrate and the first surface of the flexible layer. The adhesive allows some portion of light to pass through the adhesive and has a viscosity that substantially fills in a texture of at least one of the second surface of the substrate and the first surface of the flexible layer. The adhesive also forms substantially no air gaps.

Yet another aspect of the invention may provide a method of manufacturing an assembly. The method includes the steps of: providing a substrate with a first surface and a second surface opposite the first surface; providing a flexible layer with a first surface and a second surface opposite the first surface; placing an adhesive on at least one of the second surface of the substrate and the first surface of the flexible layer; filling in a texture of at least one of the second surface of the substrate and the first surface of the flexible layer with the adhesive; and pressing together the substrate, the adhesive, and the flexible layer. The substrate allows some portion of light to pass through the first surface and the second surface. The flexible layer allows some portion of light to pass through the first surface and the second surface.

Other objects, advantages and salient features of the invention will become apparent from the following detailed description, which, taken in conjunction with the annexed drawings, discloses exemplary embodiments of the present invention.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a front elevational view of an assembly according to an exemplary embodiment of the present invention;

FIG. 2 is a cross-sectional view of the assembly illustrated in FIG. 1 along line 2-2;

FIG. 3 is a side elevational view of an apparatus for manufacturing the assembly illustrated in FIG. 1;

FIG. 4 is a side elevational view of the apparatus illustrated in FIG. 3 with an upper die set and a lower die set closed;

FIG. 5 is a perspective view showing a step in the manufacture of the assembly illustrated in FIG. 1;

FIG. 6 is a perspective view showing another step in the manufacture of the assembly illustrated in FIG. 1;

FIG. 7 is a perspective view showing another step in the manufacture of the assembly illustrated in FIG. 1;

FIG. 8 is a perspective view showing another step in the manufacture of the assembly illustrated in FIG. 1;

FIG. 9 is a perspective view showing another step in the manufacture of the assembly illustrated in FIG. 1;

FIG. 10 is a perspective view showing another step in the manufacture of the assembly illustrated in FIG. 1;

FIG. 11 is a perspective view showing another step in the manufacture of the assembly illustrated in FIG. 1;

FIG. 12 is a perspective view showing another step in the manufacture of the assembly illustrated in FIG. 1;

FIG. 13 is a perspective view showing another step in the manufacture of the assembly illustrated in FIG. 1;

FIG. 14 is a perspective view showing another step in the manufacture of the assembly illustrated in FIG. 1; and

FIG. 15 is a perspective view showing another step in the manufacture of the assembly illustrated in FIG. 1

### DETAILED DESCRIPTION OF THE INVENTION

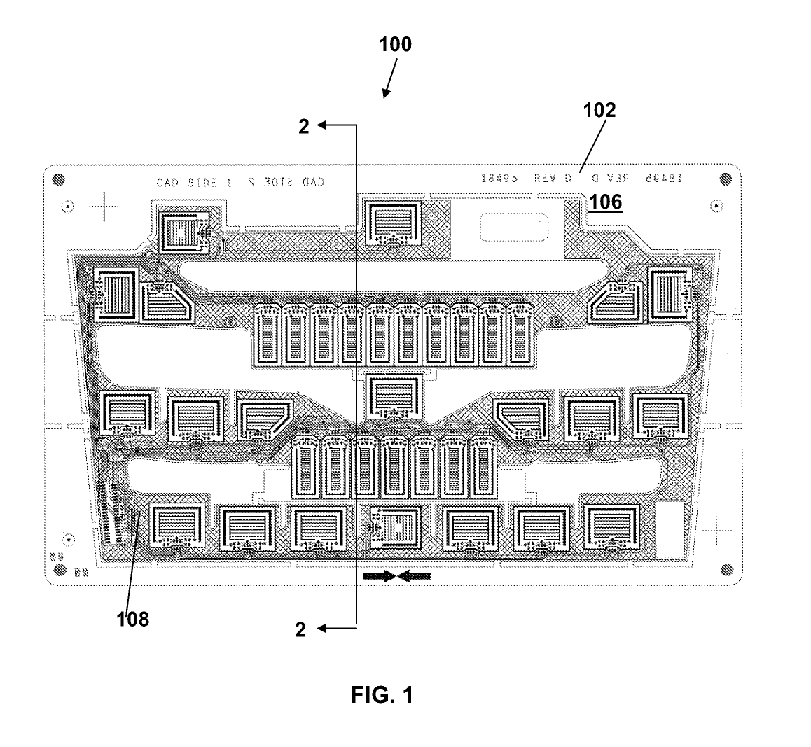

Referring to FIGS. 1-15, the present invention provides an apparatus and a method for illuminating a circuit board such that the light traveling through the circuit board does not substantially change color or lose its intensity. Also, the apparatus and method may be used with lead free solder and two-sided traces.

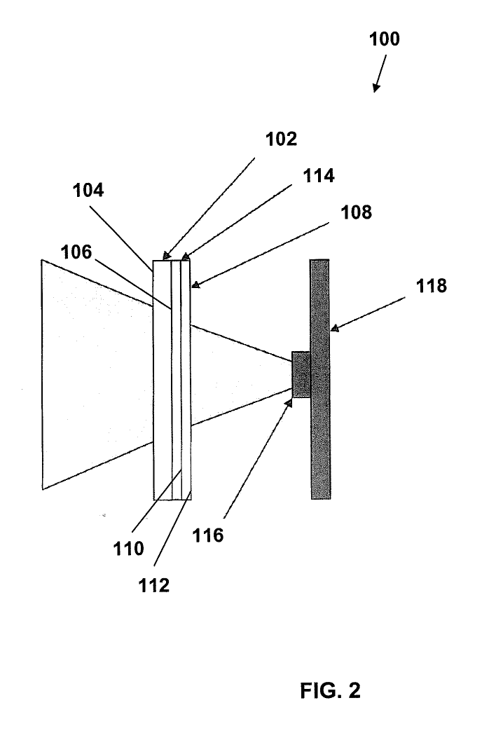

Turning to FIGS. 1 and 2, an assembly 100 is shown. The assembly 100 includes a substrate 102 with a first surface 104 and a second surface 106 opposite the first surface 104, a flexible layer 108 with a first surface 110 and a second surface 112 opposite the first surface 110, and an adhesive 114 between the substrate 102 and the flexible layer 108. In the embodiment shown, the assembly 100 is illuminated by a light source 116. The depicted light source 116 is mounted to an illumination printed circuit board 118. However, in other embodiments, the light source 116 need not be mounted to an illumination printed circuit board 118. Also, the light source 116 can be an incandescent bulb, fluorescent bulb, light emitting diode, combinations of the aforementioned, or any other device that provides light or illumination.

For the sake of simplifying the description, the invention is described in reference to an embodiment where the assembly 100 provides a substrate 102 with which a user interacts. The user interactions on the first surface 104 of the substrate 102 actuate one or more capacitive or field effect devices disposed on the flexible layer 108 adjacent to the substrate 102. The first surface 104 of the substrate 102 can include indicia such as words, diagrams, pictures, signs, and other indicators that can be imprinted, printed, etched, sculpted, painted, adhered, or other mated to the first surface 104. The user touches the first surface 104 near one or more of the capacitive or field effect devices, and the touch on the first surface 104 actuates the one or more capacitive or field effect devices disposed on the flexible layer 108. Such an assembly 100 can be used, for example, in an automobile to control or manipulate one or more functions of a system of the automobile. For example, the first surface 104 of the substrate 102 can have indicia for temperature control and the flexible layer 108 can have a capacitive device associated with the indicia for temperature control. The light source 116 can emit light through the substrate 102 and the flexible layer 108 and thus illuminate the indicia for temperature control on the first surface 104 of the substrate 102 and the associated capacitive device on the flexible layer 108 such that the user can visually perceive the indicia and the associated capacitive device. Thus, when the user touches the first surface 104 near the indicia for temperature control, the associated capacitive device on the flexible layer 108 is actuated and sends a signal that changes the temperature setting of an air conditioning system or heating system. However, the invention is not limited to such an embodiment and can be applied to any assembly 100 that requires a substantially transparent or translucent flexible layer 108 coupled to a substrate 102.

The substrate 102 can provide mechanical support, an interface for a user, a surface 104 for decorative features, combinations of the aforementioned, or some other similar function. Although the substrate 102 is shown as being a generally flat board, the substrate 102 can have an irregular shape or contour. The second surface 106 of the substrate may be mated to the flexible layer 108. The substrate 102 can be made from plastic, thermoset, thermoset polyethylene, thermoplastic such as acrylic or acrylonitrile butadiene styrene, thermoplastic polymer such as polycarbonate, thermoplastic fluoropolymer, fluorocarbon-based polymer, polyethylene, polyvinyl chlorides, polyvinylidene fluoride, ethylene tetrafluoroethylene, silicone, glass, combinations of the aforementioned, or any other rigid material that is substantially transparent, translucent, or allows some portion of light to pass. In the embodiment shown, the substrate 102 is made from polycarbonate and acrylonitrile butadiene styrene (ABS).

The flexible layer 108 provides a surface 110 or 112 for mounting components. The flexible layer 108 is flexible so that it can substantially match the shape and contour of the substrate 102. The flexible layer 108 is also substantially transparent, translucent, or white to allow at least a portion of light to travel through it with substantially no change in the color or intensity of the light. In the embodiment shown, components are mounted on the surface 110 or 112 to form one or more circuits. The components can be surface mount resistors, application specific integrated circuits, capacitors, connectors, traces, or some other component that provides a pathway for an electrical signal or manipulates an electrical signal. The flexible layer 108 can be made from a polytetrafluoroethylene (PTFE) film, plastic, thermoset, thermoset polyethylene, thermoplastic such as acrylic or acrylonitrile butadiene styrene, thermoplastic polymer such as polycarbonate, thermoplastic fluoropolymer, fluorocarbon-based polymer, polyethylene, polyvinyl chlorides, polyvinylidene fluoride, ethylene tetrafluoroethylene, silicone, constructs containing glass or glass fibers, combinations of the aforementioned, or any other rigid material that is substantially transparent or translucent and flexible enough to conform to the shape and contours of the substrate. In the embodiment shown, the flexible layer 108 is made from thin, flexible FR408 with substantially no ultraviolet inhibitors or doping. FR408 is made from resin-reinforced glass fibers and is commercially available from Isola Global. Also, a flexible layer 108 with a thickness of approximately 0.08 mm provides optimal characteristics for light transmission and flexibility for matching the contours of the substrate 102.

The adhesive 114 couples the substrate 102 and the flexible layer 108. The adhesive 114 can be substantially transparent, translucent, or allow some portion of light to pass so that, when the adhesive 114 is used to mate the substrate 102 and the flexible layer 104, the adhesive 114 allows at least some portion of light to pass without substantially changing the color or intensity of the light. Furthermore, the adhesive 114 can form a thin mating that is more reliable and more uniform than a mating formed from pressure sensitive tape and adhesives. The adhesive 114 can be a solvent-free plastic adhesive (such as acrylated urethane commercially available as Dymax 3069), a solvent-free glob top chip encapsulant (such as modified urethane commercially available as the Dymax 9001 series of adhesives), modified acrylate (such as those commercially available as the Loctite 3492 series of adhesives or the Loctite 3493 series of adhesives), modified acrylic (such as those commercially available as the Loctite 3494 series of adhesives), or any other appropriate adhesive that cures substantially transparent or translucent. The adhesive 114 can be an ultraviolet light (UV) or natural light curable adhesive. In an embodiment using UV light curable adhesive, the flexible layer 108 has substantially no UV blocking agent so that UV light can substantially pass through the flexible layer 108 to cause curing of the UV light curable adhesive. In the embodiment shown, the adhesive is a UV or natural light curable adhesive, such as Dymax 3069, and the flexible layer 108 is made from FR408 with substantially no UV blocking agent. In other embodiments, the adhesive 114 can be a heat curable adhesive such as thermoplastic or chemical reaction curable adhesive such as polyvinyl acetate, epoxy, polyurethane, cyanoacrylate polymers, polychloroprene, acrylate based polymers, a resin and its corresponding accelerant, and similar adhesives.

Before curing, the adhesive 114 can be disposed on either the second surface 106 of the substrate or the first surface 110 of the flexible layer 108 as a thin, uniform coating. Also, when the adhesive 114 is made from UV or natural light curable adhesive, it substantially prevents formation of air gaps between the substrate 102 and the flexible layer 108. Thus, when a capacitive or field effect circuit, device, or sensor is placed on the flexible layer 108, air gaps do not substantially impair the performance of the capacitive or field effect circuit, device, or sensor.

In addition, in the embodiment where the adhesive 114 is a UV or natural light curable adhesive, the adhesive 114 can aid in making the substrate 102 or the flexible layer 108 more transparent, more translucent, or allow at least some portion of light to pass more readily. If the adhesive 114 has a viscosity so that it allows the adhesive 114 to fill in the texture of the surface 104, 106, 110, or 112, then the adhesive 114 can make the substrate 102 or the flexible layer 108 more transparent, more translucent, or allow some portion of light to pass more readily. Such an adhesive 114 acts as a wetting agent and allows more light to pass through the substrate 102 or the flexible layer 108.

The flexible layer 108 may be connected to the illumination printed circuit board 118 by an electrical pathway. In the embodiment shown, a flat flexible cable (FFC) connector connects the flexible layer 108 and the illumination circuit board 118. In other embodiments, the flexible layer 108 and the illumination circuit board 118 can be connected by a trace, a wire, a cable, a coaxial cable, a wireless transmission path, combinations of the aforementioned, or any other pathway for signals between two components.

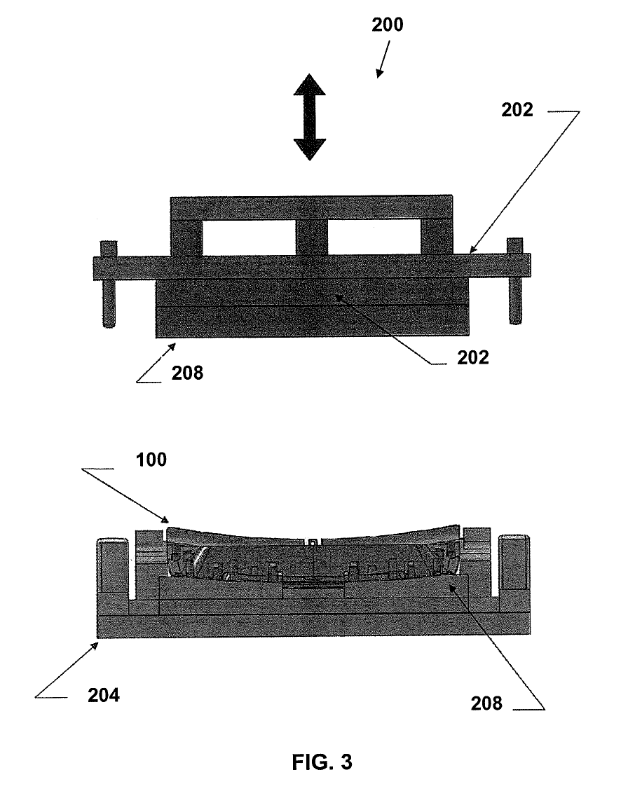

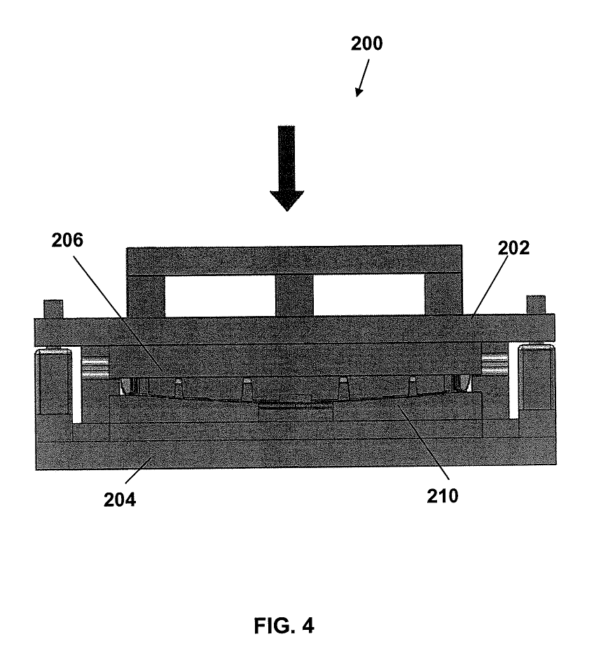

Referring to FIGS. 3-4, an apparatus 200 for manufacturing the assembly 100 is shown. Turning to FIG. 3, the apparatus 200 includes an upper die set 202 and a lower die set 204. The terms “upper” and “lower” are not meant to be limiting but are used to describe the relative positions of the components within the apparatus 200. For example, in another embodiment, the die sets 202 and 204 may be oriented laterally so that the die sets 202, 204 are to the right or left of each other or some other orientation. The upper die set 202 can be moved towards or away from the lower die set 204 as indicated by the arrows in the figure. In FIG. 3, the upper die set 202 and the lower die set 204 are apart from each other.

The upper die set 202 includes a curing light source 206 and a pressure pad 208. The curing light source 206 emits a light that causes curing of the adhesive 114. The curing light source 206 can be one or more light emitting diodes, metal halide bulbs, or the like. The pressure pad 208 presses together the substrate 102 and the flexible layer 108 so that the flexible layer 108 conforms to the irregular shape or contours of the substrate 102. The substrate 102 and the flexible layer 108 may be disposed in the lower die set 204, and the pressure pad 208 provides substantially uniform pressure to press together the substrate 102 and the flexible layer 108 when the upper die set 202 is pressed towards the lower die set 204. In the embodiment shown, the pressure pad 208 is between the curing light source 206 and lower die set 204. Also, the curing light source 206 emits light of approximately 6 mW/cm² and approximately 365 nm to cure the UV light curable adhesive. The depicted pressure pad 208 is a substantially continuous surface. In other embodiments, the pressure pad 208 can formed from a lattice structure or a surface that is not continuous. However, a pressure pad 208 formed from a lattice structure is less efficient and forms a less reliable mating of the substrate 102 and the flexible layer 108. A lattice structure pressure pad 208 causes a “doming” effect in the adhesive 114 between the substrate 102 and the flexible layer 108, and the “doming” effect produces an adhesive 114 with an inconsistent thickness. In an embodiment where the adhesive 114 is a heat curable or chemical reaction curable adhesive, the curing light source 206 is replaced with a heat source.

The lower die cast 204 includes a nest 210. The nest 210 receives the substrate 102, the adhesive 114, and the flexible layer 108. The adhesive 114 is placed between the substrate 102 and the flexible layer 108 so that when the upper die set 202 is pressed towards the lower die set 204, the adhesive 114 is pressed between the substrate 102 and the flexible layer 108 so that the substrate 102 and the flexible layer 108 are mated. The nest 210 is shaped to conform to the first surface 104 of the substrate 102.

Turning to FIG. 4, after the substrate 102, the adhesive 114, and the flexible layer 108 are placed in the nest 210 of the lower die set 204, the upper die set 202 is pressed towards the lower die set 204. When the upper die set 202 is pressed toward the lower die set 204, the substrate 102, the adhesive 114, and the flexible layer 108 are pressed together between the pressure pad 208 and the nest 210. The pressure pad 208 presses together the substrate 102, the adhesive 114, and the flexible layer 108 to ensure that flexible layer 108 substantially conforms to the shape and contour of the substrate 102. The pressure pad 208 also ensures that the adhesive 114 is substantially thin, uniform, and has no air gaps. After the substrate 102, the adhesive 114, and the flexible layer 108 are pressed together, the curing light source 206 is actuated, and the light emitted from the curing light source 206 causes curing of the adhesive 114. After the adhesive 114 is substantially cured, the upper die set 202 is moved away from the lower die set 204, and the finished assembly 100 is removed from the nest 210.

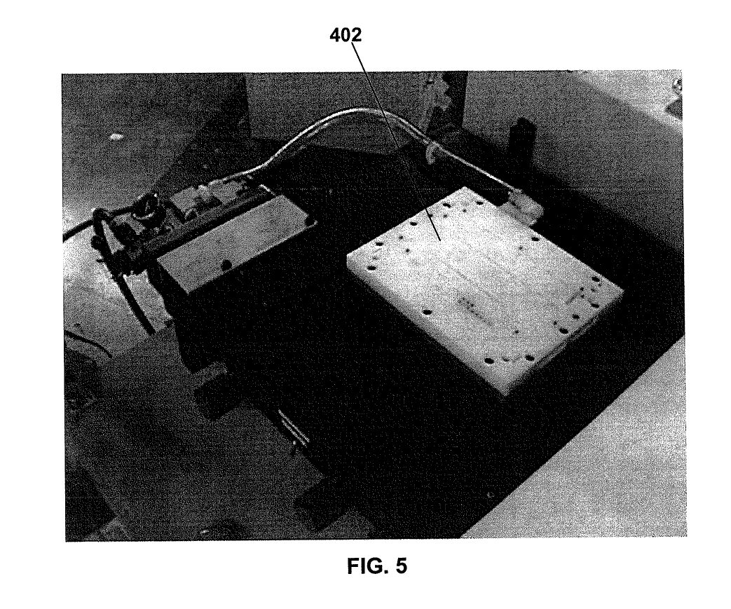

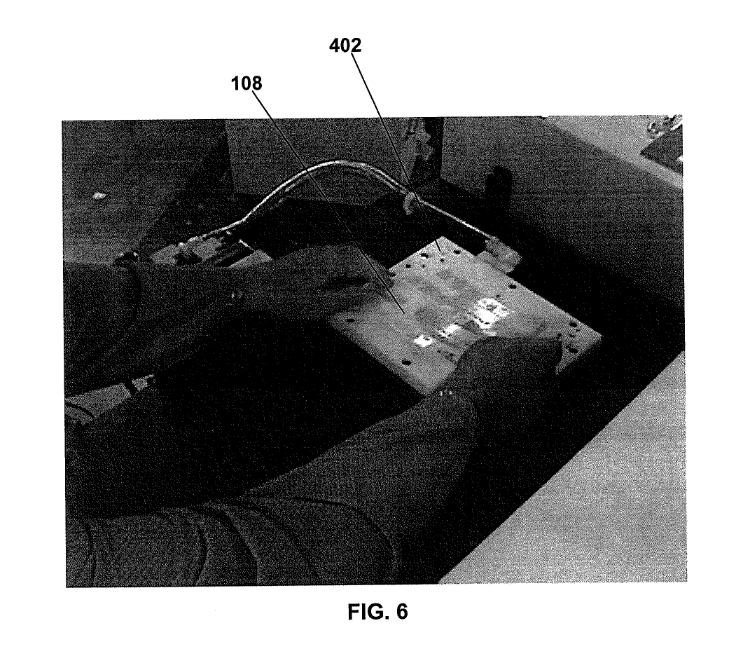

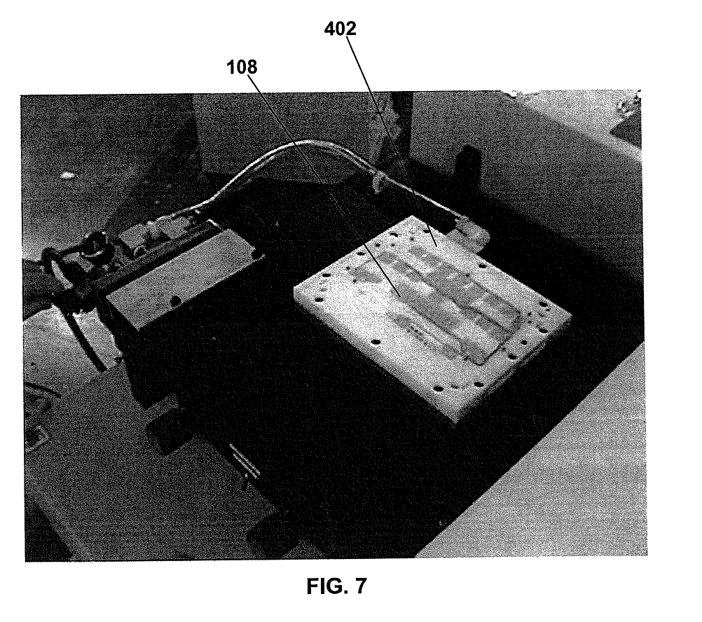

Referring to FIGS. 5-15, steps in a method 300 of manufacturing the assembly 100 are shown. The steps shown are not meant to be limiting to the invention. Instead, the illustrated steps show one exemplary embodiment of the method 300 of manufacturing the assembly 100. One or more of the steps may be omitted in other embodiments, or the steps may be performed in an order different from the one shown in FIGS. 5-15. Turning to FIG. 5, an adhesive stencil fixture 402 is provided, step 302. Referring to FIG. 6, a flexible layer 108 is placed on the adhesive stencil fixture 402, step 304. In the embodiment shown, the flexible layer 108 includes components to form a circuit. Referring to FIG. 7, the flexible layer 108 is shown disposed in the adhesive stencil fixture 402.

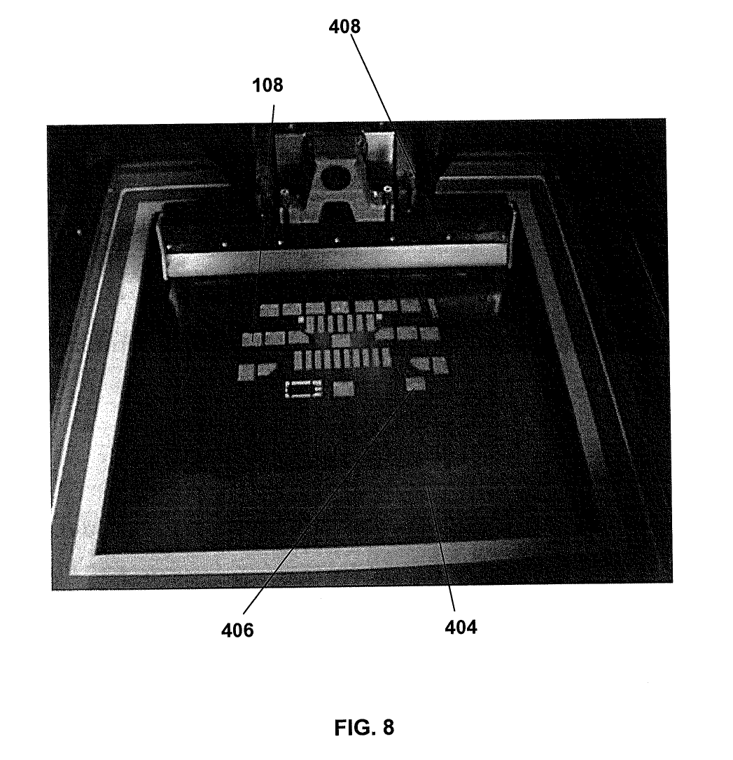

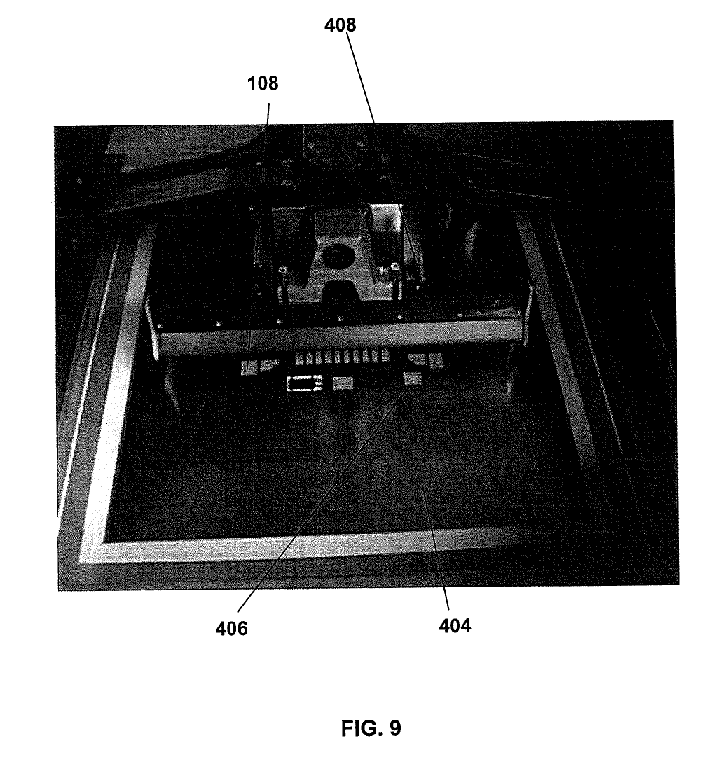

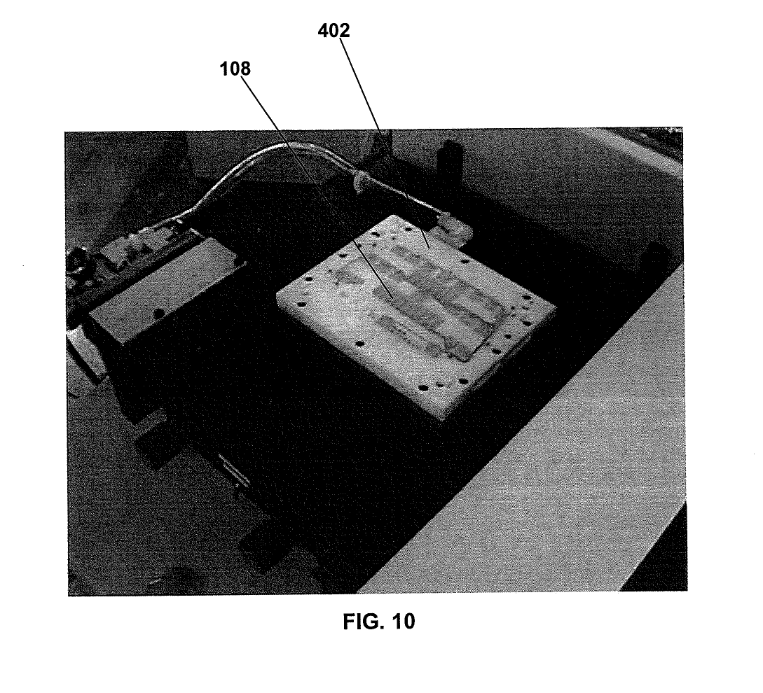

Referring to FIG. 8, an adhesive stencil 404 is placed over the flexible layer 108 and the adhesive stencil fixture 402, step 306. The adhesive stencil 404 has one or more apertures 406 that expose the underlying flexible layer 108 so that uncured adhesive 114 is applied to only predetermined portions of the flexible layer 108 exposed by the apertures 406. Also, an applicator 408 is placed over the adhesive stencil 404. Referring to FIG. 9, the applicator 408 moves over the adhesive stencil 404 and applies uncured adhesive 114 to the adhesive stencil 404, step 308. As the applicator 408 applies the uncured adhesive 114 to the adhesive stencil 404, the uncured adhesive 114 is applied to only the portions of the flexible layer 108 exposed by the apertures 406. Referring to FIG. 10, applicator 408 and the adhesive stencil 404 are removed, step 310. Thus, uncured adhesive 114 is disposed on portions of the flexible layer 108. The flexible layer 108 is shown disposed in the adhesive stencil fixture 402.

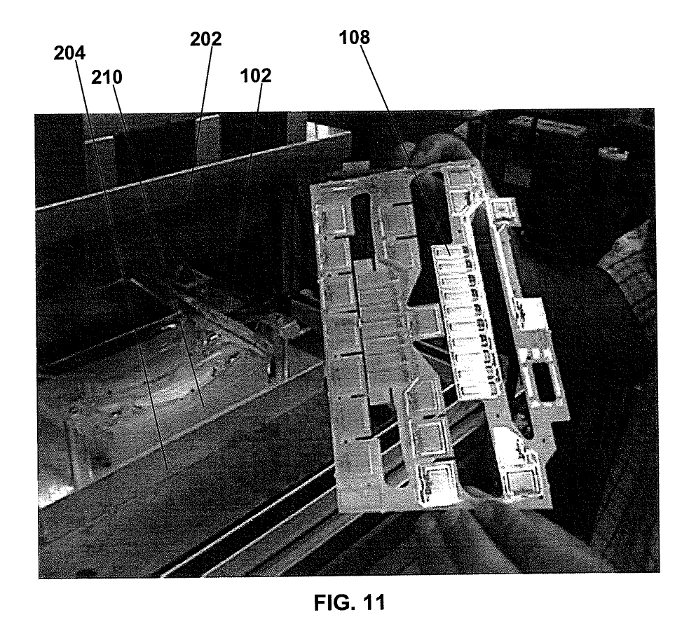

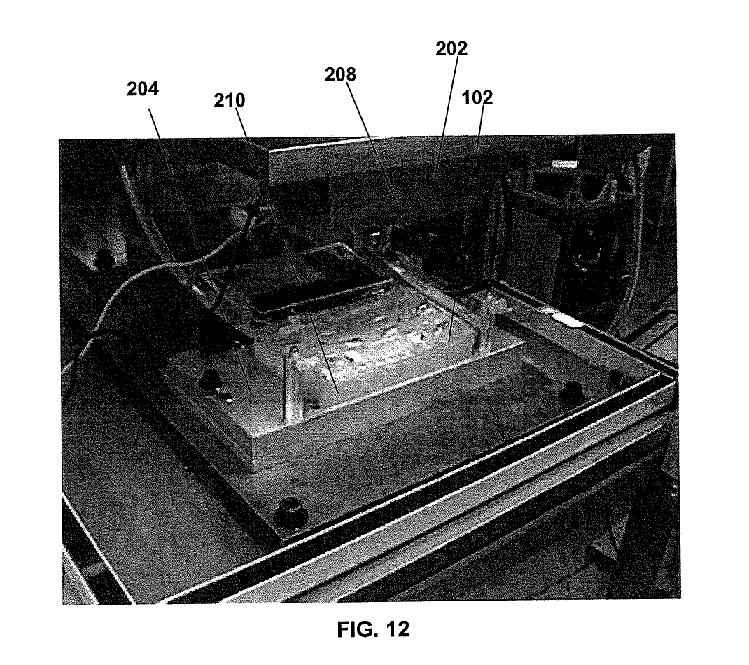

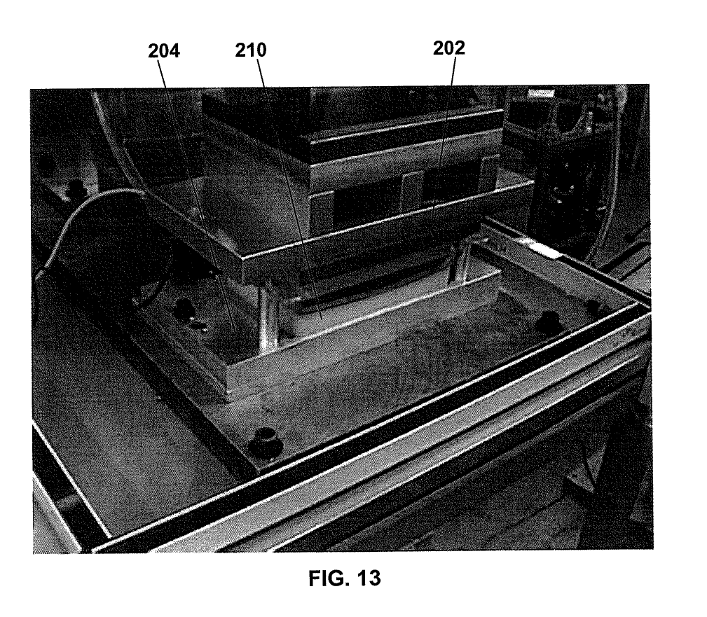

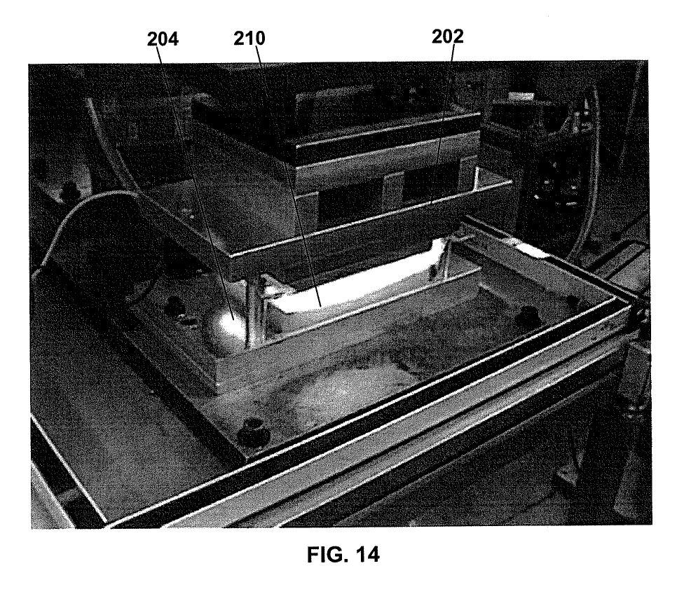

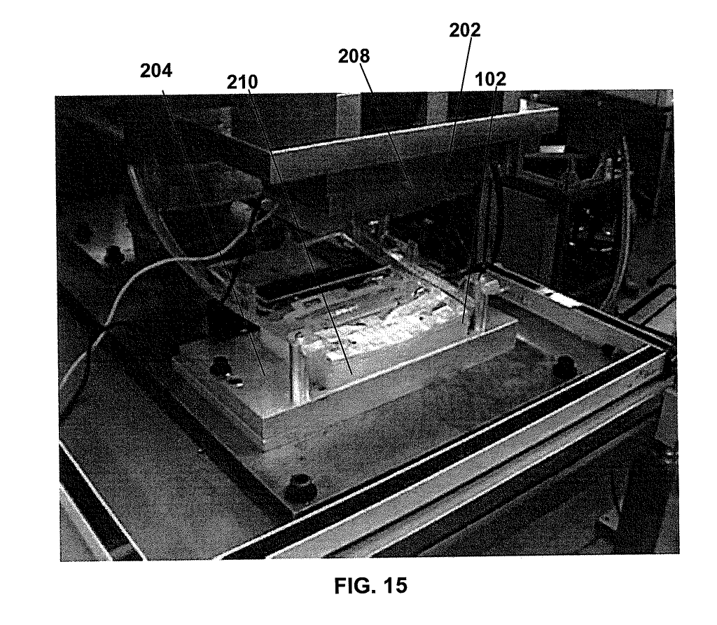

Referring to FIG. 11, the flexible layer 108 with uncured adhesive 114 is removed from the adhesive stencil fixture 402, step 312. The substrate 102 is disposed in the nest 210 of the lower die set 204, step 314. Referring to FIG. 12, the flexible layer 108 with uncured adhesive 114 is disposed on the substrate 102 such that the uncured adhesive 114 is between portions of the flexible layer 108 and the substrate 102, step 316. Referring to FIG. 13, the upper die set 202 is pressed towards the lower die set 204, step 318. Referring to FIG. 14, as the upper die set 202 is pressed towards the lower die set 204, the curing light source 204 is actuated, step 320. The light from the curing light source 204 causes curing of the uncured adhesive 114. Referring to FIG. 15, the upper die set 202 is moved away from the lower die set 204 when the uncured adhesive 114 is substantially cured, step 322.

While particular embodiments have been chosen to illustrate the invention, it will be understood by those skilled in the art that various changes and modifications can be made therein without departing from the scope of the invention as defined in the appended claims.

What is claimed is:

1. An assembly, the assembly comprising:
a substrate with a first surface and a second surface opposite the first surface;
a flexible layer with a first surface and a second surface opposite the first surface, the flexible layer having a thickness such that light passes through the flexible layer without substantial change to a color or an intensity of the light and such that the flexible layer substantially conforms to a shape of the substrate; and
an adhesive coupling the second surface of the substrate and the first surface of the flexible layer, the adhesive having a viscosity that substantially fills in a texture of at least one of the second surface of the substrate and the first surface of the flexible layer, the adhesive forming substantially no air gaps.

2. The assembly according to claim 1, wherein the flexible layer is substantially transparent.

3. The assembly according to claim 1, wherein the flexible layer is substantially translucent.

4. The assembly according to claim 1, wherein the flexible layer is substantially white.

5. The assembly according to claim 1, wherein the flexible layer is made from FR408.

6. The assembly according to claim 1, wherein the adhesive is an ultraviolet light curable adhesive.

7. The assembly according to claim 1, further comprising a capacitive device on the second surface of the flexible layer.

8. The assembly according to claim 1, further comprising a light source disposed adjacent to the second surface of the flexible layer.

9. An assembly, the assembly comprising:
a substrate with a first surface and a second surface opposite the first surface, the substrate allowing some portion of light to pass through the first surface and the second surface;
a flexible layer with a first surface and a second surface opposite the first surface, the flexible layer allowing some portion of light to pass through the first surface and the second surface, the flexible layer having a thickness such that light passes through the flexible layer without substantial change to a color or an intensity of the light and such that the flexible layer substantially conforms to a shape of the substrate; and
an adhesive coupling the second surface of the substrate and the first surface of the flexible layer, the adhesive allowing some portion of light to pass through the adhesive, the adhesive having a viscosity that substantially fills in a texture of at least one of the second surface of the substrate and the first surface of the flexible layer, the adhesive forming substantially no air gaps.

10. The assembly according to claim 9, wherein the flexible layer is substantially white.

11. The assembly according to claim 9, wherein the flexible layer is made from FR408.

12. The assembly according to claim 9, wherein the adhesive is an ultraviolet light curable adhesive.

13. The assembly according to claim 9, further comprising a capacitive device on the second surface of the flexible layer.

14. A method of manufacturing an assembly, comprising the steps of:
providing a substrate with a first surface and a second surface opposite the first surface and that allows some portion of light to pass through the first surface and the second surface;
providing a flexible layer with a first surface and a second surface opposite the first surface and that allows some portion of light to pass through the first surface and the second surface;
disposing an adhesive on at least one of the second surface of the substrate and the first surface of the flexible layer;
filling in a texture of at least one of the second surface of the substrate and the first surface of the flexible layer with the adhesive; and
pressing together the substrate, the adhesive, and the flexible layer.

15. The method of manufacturing the assembly according to claim 14, wherein the adhesive allows some portion of light to pass.

16. The method of manufacturing the assembly according to claim 14, wherein the adhesive is an ultraviolet light curable adhesive.

17. The method of manufacturing the assembly according to claim 16, further comprising the step of curing the adhesive with ultraviolet light.

18. The method of manufacturing the assembly according to claim 17, wherein the step of curing the adhesive with ultraviolet light further comprises emitting ultraviolet light through the substrate to cause curing of the adhesive.

19. The method of manufacturing the assembly according to claim 14, wherein the step of providing the flexible adhesive further comprises providing the flexible adhesive with a substantially white color.

20. The method of manufacturing the assembly according to claim 14, wherein the step of providing the flexible layer further comprises forming the flexible layer from FR408.
